(19) United States
(12) Patent Application Publication
(10) Pub. No.: US 2021/0057658 A1
(43) Pub. Date: Feb. 25, 2021

(54) FLEXIBLE PACKAGING STRUCTURE AND FLEXIBLE DISPLAY PANEL

(71) Applicant: WUHAN CHINA STAR OPTOELECTRONICS SEMICONDUCTOR DISPLAY TECHNOLOGY CO., LTD., Wuhan, Hubei (CN)

(72) Inventor: E CHEN, Wuhan, Hubei (CN)

(21) Appl. No.: 16/639,748

(22) PCT Filed: Nov. 18, 2019
(86) PCT No.: PCT/CN2019/119291

§ 371 Date: Feb. 18, 2020

(30) Foreign Application Priority Data
Aug. 20, 2019 (CN) 201910766493.2

(51) Int. Cl. H01L 51/00; H01L 51/56; H01L 51/52

(52) U.S. Cl. CPC H01L 51/0097; H01L 51/5253; H01L 51/56

(57) ABSTRACT

A flexible packaging structure and a flexible display panel are disclosed. The flexible packaging structure of the present application adds an additional organic layer over an original organic layer at a position of a non-display area corresponding to the flexible display panel, thereby enhancing a coverage of contaminant particles in the non-display area and improving a packaging yield. In addition, the flexible packaging structure does not add the organic layer at a position corresponding to a bending area of the flexible display panel. An inorganic layer is directly deposited on the original organic layer, so that a groove structure is formed in the bending area of the flexible packaging structure, thereby improving bending performance.

The present application claims priority to Chinese Patent Application No. 201910766493.2, titled “Flexible Packaging Structure and Flexible Display Panel”, filed on Aug. 20, 2019 with the National Intellectual Property Administration, which is incorporated by reference in the present application in its entirety.

### FIELD OF INVENTION

The present application relates to the field of display technology, and in particular, to a flexible packaging structure and a flexible display panel.

### BACKGROUND

With rapid development of organic light emitting diode (OLED) display technology, curved surfaces and flexible display products are rapidly entering the market, and technological updates in related fields are also changing with each passing day. OLED devices are diode devices that use organic light-emitting materials to drive light through carrier injection and recombination under an electric field. In recent years, active-matrix organic light emitting diode (AMOLED) display devices that use currents to drive OLED devices to emit light for forming images have received widespread attention due to advantages of high contrast, wide viewing angles, fast response times, bendability, etc.

### Technical Problem

Since the light-emitting materials of OLED devices are very sensitive to moisture and oxygen, how to effectively prevent damage to OLED devices from external moisture and oxygen to ensure that the devices have a long service life is also one focus and difficulty of current flexible OLED researches. Currently, more mature flexible packaging processes are generally implemented on OLED devices, using inorganic/organic multiple alternating thin film packaging structures. Among them, inorganic layers are generally fabricated by a chemical vapor deposition (CVD) process, and a thickness thereof is less than or equal to 1 μm. The inorganic layers are mainly used to block moisture and oxygen and prevent light from dimming due to an intrusion of moisture or oxygen into the OLED devices. Organic layers are generally fabricated by an inkjet printing (IJP) process, and are mainly used to planarize surfaces of substrates, encapsulate contaminant particles, and relieve stress. A thickness of the organic layers is generally 8-10 μm. In order to achieve bending of a display panel, the organic layers in the thin-film encapsulation structure will be continuously thinned (less than 8 μm, possibly thinner), so as to relieve stress of adjacent inorganic layers during bending and reduce peeling or occurrence of cracking. However, with thinning of the organic layers, their ability to cover contaminant particles will obviously weaken, and risks of package failure will increase significantly. Control of contaminant particles is a problem in the industry for production lines, and weakening of the coverage of polluting particles greatly affects a packaging yield of the production lines.

### Technical Solution

An object of the present application is to provide a flexible packaging structure and a flexible display panel to solve the problems in the prior art, which can improve the packaging yield of the display panel and also improve the bending performance of the display panel.

In order to achieve the foregoing object of the present invention, an embodiment of the present invention provides flexible packaging structure, comprising a display area; a non-display area surrounding the display area; and a bending area passing through the display area and the non-display area. The flexible packaging structure comprises a first dam is disposed in the non-display area, surrounding an edge of a light emitting device layer disposed over an array substrate; a first inorganic layer completely covering the first dam, the light emitting device layer, and the array substrate; a first organic layer deposited over the first inorganic layer and disposed on a side of the first dam close to the display area; a second organic layer is deposited over the first organic layer in the non-display area, wherein the second organic layer is disposed between the first dam and the display area, and does not cover the bending area, and the second organic layer is made of an acrylic material or an epoxy resin material; and a second inorganic layer completely covering the second organic layer, the first organic layer, and the first inorganic layer, and the second inorganic layer is deposited on the first organic layer in the bending area, such that a groove structure is formed in the bending area of the flexible packaging structure.

In order to achieve the foregoing object of the present invention, an embodiment of the present invention further provides a flexible packaging structure, comprising a display area and a non-display area surrounding the display area. The flexible packaging structure comprises a first dam is disposed in the non-display area, surrounding an edge of a light emitting device layer disposed over an array substrate; a first inorganic layer completely covering the first dam, the light emitting device layer, and the array substrate; a first organic layer deposited over the first inorganic layer and disposed on a side of the first dam close to the display area; a second organic layer is deposited over the first organic layer in the non-display area and disposed between the first dam and the display area; and a second inorganic layer completely covering the second organic layer, the first organic layer, and the first inorganic layer.

In order to achieve the foregoing object of the present invention, an embodiment of the present invention further provides a flexible display panel, comprising a display area and a non-display area surrounding the display area. The flexible display panel comprises an array substrate; a light emitting device layer formed over the array substrate; and a flexible packaging structure formed over the light emitting device layer. The flexible packaging structure comprises a first dam is disposed in the non-display area, surrounding an edge of a light emitting device layer disposed over an array substrate; a first inorganic layer completely covering the first dam, the light emitting device layer, and the array substrate; a first organic layer deposited over the first inorganic layer and disposed on a side of the first dam close to the display area; a second organic layer is deposited over the first organic layer in the non-display area and disposed between the first dam and the display area; and a second inorganic layer completely covering the second organic layer, the first organic layer, and the first inorganic layer.

### Advantageous Effects

A flexible packaging structure of the present application adds an additional organic layer over an original organic layer at a position of a non-display area corresponding to a flexible display panel. This additional organic layer has a good ability to cover contaminant particles and has good adhesion to an inorganic layer, thereby enhancing a coverage of contaminant particles in the non-display area and improving a packaging yield. In addition, the flexible packaging structure does not add an organic layer at a position corresponding to a bending area of the flexible display panel. The inorganic layer is directly deposited on the original organic layer, so that a groove structure is formed in the bending area of the flexible packaging structure, thereby improving bending performance.

### BRIEF DESCRIPTION OF DRAWINGS

To detailly explain the technical schemes of the embodiments or existing techniques, drawings that are used to illustrate the embodiments or existing techniques are provided. Obviously, the illustrated embodiments are just a part of those of the present disclosure. It is easy for any person having ordinary skill in the art to obtain other drawings without labor for inventiveness.

FIG. 1 is a plan view of a flexible display panel of the present application.

FIG. 2 is a cross-sectional view of a layered structure of a flexible display panel taken along line A-A′ in FIG. 1 according to an embodiment of the present application.

FIG. 3 is a cross-sectional view of a layered structure of a flexible display panel taken along a line B-B′ in FIG. 1 according to an embodiment of the present application.

### DETAILED DESCRIPTION

The embodiments of the present application are described in detail below, and examples of the embodiments are shown in the drawings, wherein the same or similar reference numerals indicate the same or similar elements or elements having the same or similar functions throughout. The embodiments described below with reference to the drawings are exemplary and are only used to explain the present application, and should not be construed as limiting the present application.

In the present application, unless explicitly stated and limited otherwise, the “first” or “under” of the second feature may comprise the first and second features in direct contact, and may also include the first and second features are not in direct contact, but through another characteristic contact between them. Moreover, the first feature is “above”, “above”, and “above” the second feature, including that the first feature is directly above and obliquely above the second feature, or merely indicates that the first feature is higher in level than the second feature. The first feature is “below”, “below”, and “below” of the second feature, comprising the fact that the first feature is directly below and obliquely below the second feature, or merely indicates that the first feature is less horizontal than the second feature.

The following disclosure provides many different implementations or examples for implementing different structures of the present application. To simplify the disclosure of this application, the components and settings of specific examples are described below. Of course, they are merely examples and are not intended to limit the application. Furthermore, the present application may repeat reference numbers and/or reference letters in different examples, and such repetition is for the sake of simplicity and clarity, and does not itself indicate a relationship between the various embodiments and/or settings discussed. In addition, examples of various specific processes and materials are provided in this application, but the people skill in the art may be aware of the application of other processes and/or the use of other materials.

The flexible display panel of the present application comprises an array substrate, a light emitting device layer formed over the array substrate, and a flexible packaging structure formed over the light emitting device layer. The flexible packaging structure is disposed at a position corresponding to a non-display area of the flexible display panel. An organic layer is additionally formed over an original organic layer. The added organic layer can be fabricated by mask-free methods such as inkjet printing and glue dispensing. The added organic layer has good coverage of contaminant particles and good adhesion to an inorganic layer, which can enhance a coverage of contaminant particles in the non-display area and improve packaging yield. The flexible packaging structure is disposed at a position corresponding to a bending area of the flexible display panel without adding an organic layer, and the inorganic layer is directly deposited over the original organic layer, so that groove structures of the flexible packaging structure can be formed in the bending area to improve bending performance.

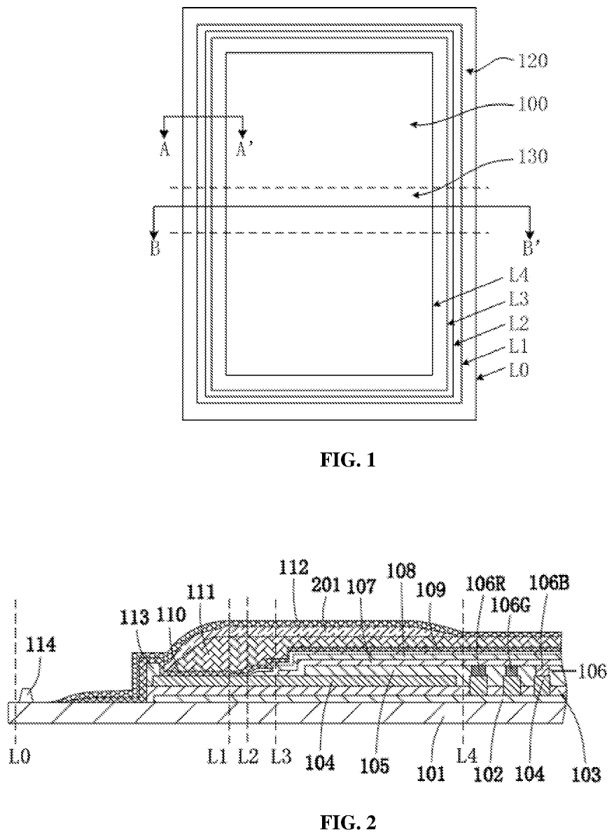

Please refer to FIGS. 1-2 at the same time, wherein FIG. 1 is a plan view of a flexible display panel of the present application, and FIG. 2 is a cross-sectional view of a layered structure of the flexible display panel taken along the line A-A′ in FIG. 1. according to an embodiment.

As shown in FIG. 1, the flexible display panel comprises a display area (i.e. active area, AA) 100 and a non-display area 120 surrounding the display area 100. A reference numeral L4 in the figure is a boundary of the display area 100, and reference numerals L1 to L3 are boundaries of different masks (see details below). The flexible display panel comprises an array substrate, a light emitting device layer formed over the array substrate, and a flexible packaging structure formed over the light emitting device layer.

As shown in FIG. 2, in this embodiment, the array substrate comprises a flexible substrate 101, a thin film transistor (TFT) array layer 102, and a planarization layer (PLN) 103 sequentially stacked. The flexible substrate 101 is generally formed of a flexible bendable material, for example, polyimide (PI). The flexible substrate 101 may be a single-layered PI layer or a multi-layered PI layer, which is not limited in this application. The TFT array layer 102 comprises a plurality of TFTs arranged in an array, and fabrication thereof may refer to an existing process, which is not limited in the present application. The planarization layer 103 mainly functions to reduce difference between in-plane segments caused by patterns of various layers over the TFT array layer 102 and isolate the TFTs from the light emitting device layer, thereby preventing interference of electric fields.

In this embodiment, the light emitting device layer comprises an anode layer 104, a pixel defining layer (PDL) 105, a light emitting material functional layer 106, a cathode layer 107, and a capping layer (CPL) 108, which are sequentially stacked, and a device protection layer 109. The light emitting material functional layer 106 comprises an electron injection layer (EIL), an electron transport layer (ETL), an emissive layer (EML), a hole injection layer (HIL), and a hole transport layer (HTL), which are fabricated in an area defined by the pixel defining layer 105. The light emitting device used in the light emitting device layer is an OLED light emitting device. The light emitting material functional layer 106 comprises at least a red light material functional layer 106R, a green light material functional layer 106G, and a blue light material functional layer 106B. Accordingly, the flexible display panel is an OLED flexible display panel. It should be noted that, in other embodiments, the light emitting device of the light emitting device layer may also be a quantum dot light emitting device, and the specific form of the light emitting device of the light emitting device layer is not limited in this application.

During fabrication, the light emitting material functional layer 106, the cathode layer 107, the capping layer 108, and the device protection layer 109 are all currently fabricated by thermal evaporation process in cooperation with corresponding mask plates. As shown in FIG. 1, reference numeral L1 is a mask plate boundary of the device protection layer 109, reference numeral L2 is a boundary of a mask of the capping layer 108, and reference numeral L3 is a boundary of a mask of the cathode layer 107. The reference numeral L4 is the boundary of the display area 100. A boundary of other evaporation masks such as masks for the electron injection layer (EIL), the electron transport layer (ETL), the hole injection layer (HIL), and the hole transport layer (HTL), and light emitting layer will be between the reference numeral L4 and the reference numeral L3.

Please continue to refer to FIG. 2, in this embodiment, the flexible packaging structure comprises a first dam 113, a first inorganic layer 110, a first organic layer 111, a second organic layer 201, and a second inorganic layer 112.

The first dam 113 is disposed in the non-display area 120, surrounding an edge of the light emitting device layer disposed over the array substrate, for preventing a material of an organic layer in the flexible packaging structure from flowing out of a coverage area of the first inorganic layer 110. Specifically, the first dam 113 is disposed over the planarization layer 103 and is disposed at an edge of the anode layer 104.

The first inorganic layer 110 completely covers the first dam 113, the light emitting device layer, and the array substrate, and a main function thereof is to isolate moisture and oxygen and prevent the light emitting from dimming due to intrusion of moisture or oxygen to the light emitting device layer (especially the light emitting material functional layer 106). The first inorganic layer 110 may be formed by a chemical vapor deposition (CVD) process, a plasma enhanced chemical vapor deposition (PECVD) process, an atomic layer deposition (ALD) process, a physical vapor deposition (PVD) process, or a sputtering process. It can be understood that a material used for the first inorganic layer 110 is an inorganic material capable of increasing blocking performance to moisture and oxygen of the device.

The first organic layer 111 is deposited over the first inorganic layer 110 and is located at a side of the first dam 113 close to the display area 100. The first organic layer 111 mainly levels a substrate surface and functions to cover contaminant particles. The first organic layer 111 may be fabricated by an inkjet printing (IJP) process. It can be understood that a material used for the first organic layer 111 is a material for buffering stress of the device during bending and folding and covering the contaminant particles. It can be understood that in some embodiments, there may be no contaminant particles.

The second organic layer 201 is deposited over the first organic layer 111 of the non-display area 130 and is disposed between the first dam 113 and the display area 100, mainly to level the substrate surface and encapsulating contaminant particles. The second organic layer 201 can be fabricated by inkjet printing or a glue dispensing process. A material used for the second organic layer 201 is an acrylic material or an epoxy resin material, which has good coverage of contaminant particles and good adhesion, and can enhance the covering ability of the contaminant particles in the whole area and be well adhered to the second inorganic layer 112 deposited later, thereby improving the packaging yield. In addition, the second organic layer 201 is disposed only in the non-display area, which can save materials and reduce the influence on the display area.

As mentioned above, during production, the light emitting material functional layer 106, the cathode layer 107, the capping layer 108, and the device protection layer 109 are all currently prepared using thermal evaporation process in cooperation with corresponding masks. In the process of thermal evaporation, a large amount of evaporation materials will be accumulated on the boundaries of each mask, and the masks are closely attached to the display substrate, so the materials accumulated on the boundaries of the masks will substantially adhere to the display substrate and act as contaminant particles, thereby increasing a risk of package failure. In an actual package reliability test, it was found that an area from the reference numeral L4 to the reference numeral L1 is also most prone to pixel shrinkage (appearing as dark spots and not displayed), which is basically due to the contaminant particles in this area. In this application, by depositing the second organic layer 201 with good coverage of contaminant particles and good adhesion on the first organic layer 111 in the area, the coverage of contaminant particles in the area can be enhanced. At the same time, the second organic layer 201 can adhere well to the second inorganic layer 112 deposited later, and improve the packaging yield.

The second inorganic layer 112 completely covers the second organic layer 201, the first organic layer 111, and the first inorganic layer 110, and its main function is to block moisture and oxygen. The second inorganic layer 112 can also be fabricated by a chemical vapor deposition process, a plasma enhanced chemical vapor deposition process, an atomic layer deposition process, a physical vapor deposition process, or a sputtering coating process. It can be understood that the material used for the second inorganic layer 112 is also an inorganic material capable of increasing blocking performance to the moisture and oxygen of the device, which may be the same as the material used for the first inorganic layer 110.

In a further embodiment, the flexible display panel further comprises a second dam 114, and the second dam 114 is disposed in the non-display area, surrounding an edge of the array substrate, so that the flexible packaging structure is disposed on a side of the second dam 114 close to the display area 100. Specifically, the second dam 114 is disposed over the planarization layer 103 and is disposed at an edge of the anode layer 104. The second dam 114 is used to prevent the organic layer material in the flexible packaging structure from flowing out of the coverage area of the first inorganic layer 110. Specifically, the first dam 113 is disposed over the flexible substrate 101 and close to a cutting line L0 of the panel, so that when the flexible display panel is cut along the cutting line L0 of the panel, cutting cracks can be prevented from extending in-plane.

The flexible packaging structure used in the flexible display panel of the present application can increase the coverage of contaminant particles in the non-display area by adding an organic layer over the original organic layer at a position corresponding to the non-display area of the flexible display panel to improve package yield.

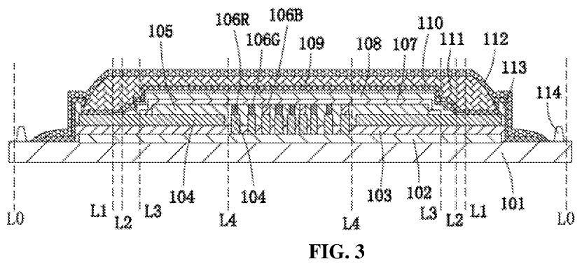

Please refer to FIG. 1 and FIG. 3 at the same time, wherein FIG. 3 is a cross-sectional view of the layered structure of the flexible display panel taken along line B-B′ in FIG. 1 according to an embodiment.

As shown in FIG. 1, the flexible display panel further comprises a bending area 130 passing through the display area 100 and the non-display area 120. In this embodiment, the bending area 130 is located in a middle of the flexible display panel, so that the flexible display panel can be folded through the bending area 130. The second organic layer 201 of the flexible packaging structure of the present application does not cover the bending area 130. In the bending area 130, the second inorganic layer 112 is directly deposited over the first organic layer 111, so that the flexible packaging structure forms a groove structure in the bending area 130, thereby improving the bending performance.

Specifically, as shown in FIG. 3, compared with the film structure of the non-bending area shown in FIG. 2, in this embodiment, the second organic layer 201 is not provided over the first organic layer 111 in the bending area. The second inorganic layer 112 is directly deposited over the first organic layer 111, so that a thickness of the flexible packaging structure of the bending area 130 is less than a thickness of the flexible packaging structure of the non-bending area. That is, the flexible packaging structure forms the groove structure in the bending area 130, so that the bending performance can be improved.

While the present disclosure has been described with the aforementioned preferred embodiments, it is preferable that the above embodiments should not be construed as limiting of the present disclosure. Anyone having ordinary skill in the art can make a variety of modifications and variations without departing from the spirit and scope of the present disclosure as defined by the following claims.

What is claimed is:

1. A flexible packaging structure, comprising:
a display area;
a non-display area surrounding the display area; and
a bending area passing through the display area and the non-display area, wherein the flexible packaging structure comprises:
a first dam disposed in the non-display area, surrounding an edge of a light emitting device layer disposed over an array substrate;
a first inorganic layer completely covering the first dam, the light emitting device layer, and the array substrate;
a first organic layer deposited over the first inorganic layer and disposed on a side of the first dam close to the display area;
a second organic layer deposited over the first organic layer in the non-display area, wherein the second organic layer is disposed between the first dam and the display area and does not cover the bending area, and the second organic layer is made of an acrylic material or an epoxy resin material; and
a second inorganic layer completely covering the second organic layer, the first organic layer, and the first inorganic layer, wherein the second inorganic layer is deposited on the first organic layer in the bending area, such that a groove structure is formed in the bending area of the flexible packaging structure.

2. The flexible packaging structure according to claim 1, wherein the first inorganic layer and the second inorganic layer are fabricated by a chemical vapor deposition process, a plasma enhanced chemical vapor deposition process, an atomic layer deposition process, a physical vapor deposition process, or a sputtering coating process.

3. The flexible packaging structure according to claim 1, wherein the first organic layer is fabricated by an inkjet printing process.

4. The flexible packaging structure according to claim 1, wherein the second organic layer is fabricated by inkjet printing or a glue dispensing process.

5. A flexible packaging structure, comprising a display area and a non-display area surrounding the display area, wherein the flexible packaging structure comprises:
a first dam disposed in the non-display area, surrounding an edge of a light emitting device layer disposed over an array substrate;
a first inorganic layer completely covering the first dam, the light emitting device layer, and the array substrate;
a first organic layer deposited over the first inorganic layer and disposed on a side of the first dam close to the display area;
a second organic layer deposited over the first organic layer in the non-display area and disposed between the first dam and the display area; and
a second inorganic layer completely covering the second organic layer, the first organic layer, and the first inorganic layer.

6. The flexible packaging structure according to claim 5, wherein the first inorganic layer and the second inorganic layer are fabricated by a chemical vapor deposition process, a plasma enhanced chemical vapor deposition process, an atomic layer deposition process, a physical vapor deposition process, or a sputtering coating process.

7. The flexible packaging structure according to claim 5, wherein the first organic layer is fabricated by an inkjet printing process.

8. The flexible packaging structure according to claim 5, wherein the second organic layer is fabricated by inkjet printing or a glue dispensing process.

9. The flexible packaging structure according to claim 5, wherein the second organic layer is made of an acrylic material or an epoxy resin material.

10. The flexible packaging structure according to claim 5, wherein the flexible packaging structure further comprises a bending area passing through the display area and the non-display area, the second organic layer does not cover the bending area, and the second inorganic layer is deposited on the first organic layer in the bending area, such that a groove structure is formed in the bending area of the flexible packaging structure.

11. A flexible display panel, comprising a display area and a non-display area surrounding the display area, wherein the flexible display panel comprises:
an array substrate;
a light emitting device layer formed over the array substrate; and
a flexible packaging structure formed over the light emitting device layer, wherein the flexible packaging structure comprises:
a first dam disposed in the non-display area, surrounding an edge of the light emitting device layer disposed over the array substrate;
a first inorganic layer completely covering the first dam, the light emitting device layer, and the array substrate;
a first organic layer deposited over the first inorganic layer and disposed on a side of the first dam close to the display area;
a second organic layer deposited over the first organic layer in the non-display area and disposed between the first dam and the display area; and
a second inorganic layer completely covering the second organic layer, the first organic layer, and the first inorganic layer.

12. The flexible display panel according to claim 11, wherein the first inorganic layer and the second inorganic layer are fabricated by a chemical vapor deposition process, a plasma enhanced chemical vapor deposition process, an atomic layer deposition process, a physical vapor deposition process, or a sputtering coating process.

13. The flexible display panel according to claim 11, wherein the first organic layer is fabricated by an inkjet printing process.

14. The flexible display panel according to claim 11, wherein the second organic layer is fabricated by inkjet printing or a glue dispensing process.

15. The flexible display panel according to claim 11, wherein the second organic layer is made of an acrylic material or an epoxy resin material.

16. The flexible display panel according to claim 11, wherein the flexible display panel further comprises a bending area passing through the display area and the non-display area, the second organic layer does not cover the bending area, and the second inorganic layer is deposited on the first organic layer in the bending area, such that a groove structure is formed in the bending area of the flexible packaging structure.

17. The flexible display panel according to claim 11, wherein the flexible display panel further comprises a second dam disposed in the non-display area, surrounding the edge of the light emitting device layer disposed over the array substrate, and the flexible packaging structure is disposed at a side of the second dam close to the display area.

18. The flexible display panel according to claim 11, wherein the light emitting device layer uses organic light emitting diode (OLED) light emitting devices or quantum dot light emitting devices.
